(19) United States
(12) Patent Application Publication
(10) Pub. No.: US 2025/0157912 A1
(43) Pub. Date: May 15, 2025

(54) SEMICONDUCTOR DEVICE

(71) Applicant: Sumitomo Electric Device Innovations, Inc., Yokohama-shi (JP)

(72) Inventor: Takuma MORI, Yokohama-shi (JP)

(73) Assignee: Sumitomo Electric Device Innovations, Inc., Yokohama-shi (JP)

(21) Appl. No.: 18/928,713

(22) Filed: Oct. 28, 2024

(30) Foreign Application Priority Data
Nov. 15, 2023 (JP) 2023-194732

(51) Int. Cl. H01L 23/498; H01L 23/00; H01L 25/16; H01L 29/06

(52) U.S. Cl. CPC H01L 23/49844; H01L 24/48; H01L 25/16; H10D 62/102; H01L 2224/48175; H01L 2224/48195; H01L 2924/1205

(57) ABSTRACT

A semiconductor device includes a substrate having a main surface and a back surface opposite to the main surface, a first FET group provided at the main surface and including a plurality of first source electrodes, a plurality of first drain electrodes, and a plurality of first gate electrodes, the plurality of first source electrodes, the plurality of first drain electrodes, and the plurality of first gate electrodes being aligned in a first direction, a second FET group provided at the main surface and including a plurality of second source electrodes, a plurality of second drain electrodes, and a plurality of second gate electrodes, the second FET group overlapping the first FET group as viewed in a second direction intersecting the first direction.

### CROSS REFERENCE TO RELATED APPLICATIONS

This application claims priority based on Japanese Patent Application No. 2023-194732 filed on Nov. 15, 2023, and the entire contents of the Japanese patent application are incorporated herein by reference.

### TECHNICAL FIELD

The present disclosure relates to a semiconductor device.

### BACKGROUND

A field effect transistor (FET) is known to have source electrode, gate electrode, and drain electrode. It is known that two FET groups each including a plurality of FETs aligned in the parallel direction of the electrodes, are arranged in the extending direction of the electrodes. It is known that a gate pad connected to the gate electrode and a drain pad connected to the drain electrode are provided between the FET groups (for example, see Patent literature 1: Japanese Unexamined Patent Application Publication No. H5-252036 and Patent literature 2: U.S. Pat. No. 11,417,746).

### SUMMARY

According to an embodiment of the present disclosure, a semiconductor device includes a substrate having a main surface and a back surface opposite to the main surface, a first FET group provided on the main surface and including a plurality of first source electrodes, a plurality of first drain electrodes, and a plurality of first gate electrodes, the plurality of first source electrodes, the plurality of first drain electrodes, and the plurality of first gate electrodes being aligned in a first direction, a second FET group provided on the main surface and including a plurality of second source electrodes, a plurality of second drain electrodes, and a plurality of second gate electrodes, the second FET group overlapping the first FET group as viewed in a second direction intersecting the first direction, a plurality of first gate pads provided on the main surface between the first FET group and the second FET group and electrically connected to the plurality of first gate electrodes and the plurality of second gate electrodes, a plurality of drain wires provided on the main surface to be arranged alternately with the plurality of first gate pads between the first FET group and the second FET group, the plurality of drain wires electrically connecting the plurality of first drain electrodes and the plurality of second drain electrodes to each other, and a drain pad electrically connected to the plurality of first drain electrodes and disposed such that the first FET group is interposed between the drain pad and the plurality of first gate pads.

### BRIEF DESCRIPTION OF THE DRAWINGS

FIG. 1 is a plan view of a semiconductor device in a first embodiment.

FIG. 2 is a plan view of a semiconductor device in the first embodiment.

FIG. 3 is an enlarged plan view of a semiconductor device according to the first embodiment.

FIG. 4 is a cross-sectional view of FIG. 3, taken along line A-A, respectively.

FIG. 5 is a B-B cross-sectional view of FIG. 3, respectively.

FIG. 6 is a C-C cross-sectional view of FIG. 3, respectively.

FIG. 7 is a D-D cross-sectional view of FIG. 3, respectively.

FIG. 8 is a plan view of a semiconductor device according to a first comparative example.

FIG. 9 is a plan view of a semiconductor device according to a second comparative example.

FIG. 10 is an enlarged plan view of a semiconductor device according to a first modification of the first embodiment.

FIG. 11 is a plan view of a semiconductor device according to a second modification of the first embodiment.

FIG. 12 is a plan view of a semiconductor device according to a third modification of the first embodiment.

FIG. 13 is a plan view of a semiconductor device according to a fourth modification of the first embodiment.

FIG. 14 is a plan view of a semiconductor device according to a fifth modification of the first embodiment.

FIG. 15 is a plan view of a semiconductor device according to a second embodiment.

FIG. 16 is an equivalent circuit diagram of FIG. 15.

FIG. 17 is a plan view of a semiconductor device in a first modification of the second embodiment.

FIG. 18 is an equivalent circuit diagram of FIG. 17.

FIG. 19 is a plan view of a semiconductor device according to a third comparative example.

### DETAILED DESCRIPTION

Since the gate pad and the drain pad are adjacent to each other, a gate-drain parasitic capacitance is generated. Thus, the characteristics of the FET deteriorate.

The present disclosure has been made in view of the above problems, and an object thereof is to make characteristics less likely to deteriorate.

### Description of Embodiments of Present Disclosure

First, the contents of embodiments of the present disclosure will be listed and explained.
(1) According to an embodiment of the present disclosure, a semiconductor device includes a substrate having a main surface and a back surface opposite to the main surface, a first FET group provided on the main surface and including a plurality of first source electrodes, a plurality of first drain electrodes, and a plurality of first gate electrodes, the plurality of first source electrodes, the plurality of first drain electrodes, and the plurality of first gate electrodes being aligned in a first direction, a second FET group provided on the main surface and including a plurality of second source electrodes, a plurality of second drain electrodes, and a plurality of second gate electrodes, the second FET group overlapping the first FET group as viewed in a second direction intersecting the first direction, a plurality of first gate pads provided on the main surface between the first FET group and the second FET group and electrically connected to the plurality of first gate electrodes and the plurality of second gate electrodes, a plurality of drain wires provided on the main surface to be arranged alternately with the plurality of first gate pads between the first FET group and the second FET group, the plurality of drain wires electrically connecting the plurality of first drain electrodes and the plurality of second drain electrodes to each other, and a drain pad electrically connected to the plurality of first drain electrodes and disposed such that the first FET group is interposed between the drain pad and the plurality of first gate pads. Thus, the gate-drain capacitance can be reduced, and the high frequency characteristics can be improved.
(2) In the above (1), the semiconductor device may further include a back-surface metal layer provided on the back surface, the back-surface metal layer being electrically connected to the plurality of first source electrodes through a plurality of first via holes overlapping the plurality of first source electrodes, respectively, as viewed in a thickness direction of the substrate and being electrically connected to the plurality of second source electrodes through each of a plurality of second via holes overlapping the plurality of second source electrodes, respectively, as viewed in the thickness direction of the substrate. Thus, the source inductance can be reduced, and the high frequency characteristics can be improved.
(3) In the above (1) or (2), the first FET group and the second FET group may be respectively provided in a first active region and a second active region in each of which the main surface is activated, and the plurality of first gate pads are provided in an inactive region in which the main surface is inactivated, the inactivate region being provided between the first active region and the second active region. Thus, the gate-source capacitance can be reduced, and the high frequency characteristics can be improved.
(4) In any one of the above (1) to (3), a width of each of the plurality of drain wires between the first FET group and the second FET group in the first direction may be smaller than a width of each of the plurality of first drain electrodes in the first direction and a width of each of the plurality of second drain electrodes in the first direction. Thus, the gate-drain capacitance can be reduced, and the high frequency characteristics can be improved.
(5) In any one of the above (1) to (4), the semiconductor device may include a second gate pad provided on the main surface such that the second FET group is interposed between the second gate pad and the plurality of first gate pads, the second gate pad being electrically connected to the plurality of second gate electrodes. Thus, the bonding wire can be bonded at two positions.
(6) In any one of (1) to (5), each of the plurality of first source electrodes may include a first portion, a second portion, and a third portion, the second portion and the third portion being aligned in the first direction to overlap the first portion as viewed in the second direction and to be provided between the first portion and a corresponding one of the first gate pads. The first FET group may include a plurality of first gate wires each provided between the second portion and the third portion and each electrically connecting at least one of the first gate electrodes to the corresponding one of the first gate pads. Thus, the gate resistance can be reduced, and the high frequency characteristics can be improved.
(7) In the above (6), each of the plurality of second source electrodes may include a fourth portion, a fifth portion, and a sixth portion, the fifth portion and the sixth portion being aligned in the first direction to overlap the fourth portion as viewed in the second direction and to be provided between the fourth portion and a corresponding one of the first gate pads. The second FET group may include a plurality of second gate wires each provided between the fifth portion and the sixth portion and each electrically connecting at least one of second gate electrodes to the corresponding one of the first gate pads. Thus, the gate resistance can be reduced, and the high frequency characteristics can be improved.
(8) In any one of the above (1) to (7), the semiconductor device may include a guard ring electrically connected to the plurality of first source electrodes and the plurality of second source electrodes on the main surface and surrounding the first FET group and the second FET group. Thus, the first FET group and the second FET group can be shielded.
(9) In any one of the above (1) to (8), the semiconductor device may include a base, a semiconductor chip mounted on the base and including the substrate, a first bonding wire connected to each of the first gate pads and extending in the second direction, and a second bonding wire connected to the drain pad and extending in a direction opposite to the second direction. Thus, the high frequency signal is equally input to the first FET group and the second FET group.
(10) In the above (5), the semiconductor device may include a base, a semiconductor chip mounted on the base and including the substrate, a first bonding wire connected to each of the first gate pads and extending in the second direction, a second bonding wire connected to the drain pad and extending in a direction opposite to the second direction, and a third bonding wire connected to the second gate pad and extending in the second direction. Thus, the interference between different signals can be reduced.
(11) In the above (10), the semiconductor device may include a first capacitor mounted on the base and having a first end electrically connected to the base and a second end to which the first bonding wire is connected, and a second capacitor mounted on the base and having a first end electrically connected to the base and a second end to which the third bonding wire is connected. Thus, the interference between different signals can be reduced.

### Details of Embodiments of Present Disclosure

Specific examples of a semiconductor device according to embodiments of the present disclosure will be described below with reference to the drawings. It is noted that the present disclosure is not limited to these examples, but is defined by the scope of the claims, and is intended to include all modifications within the meaning and scope equivalent to the scope of the claims.

### First Embodiment

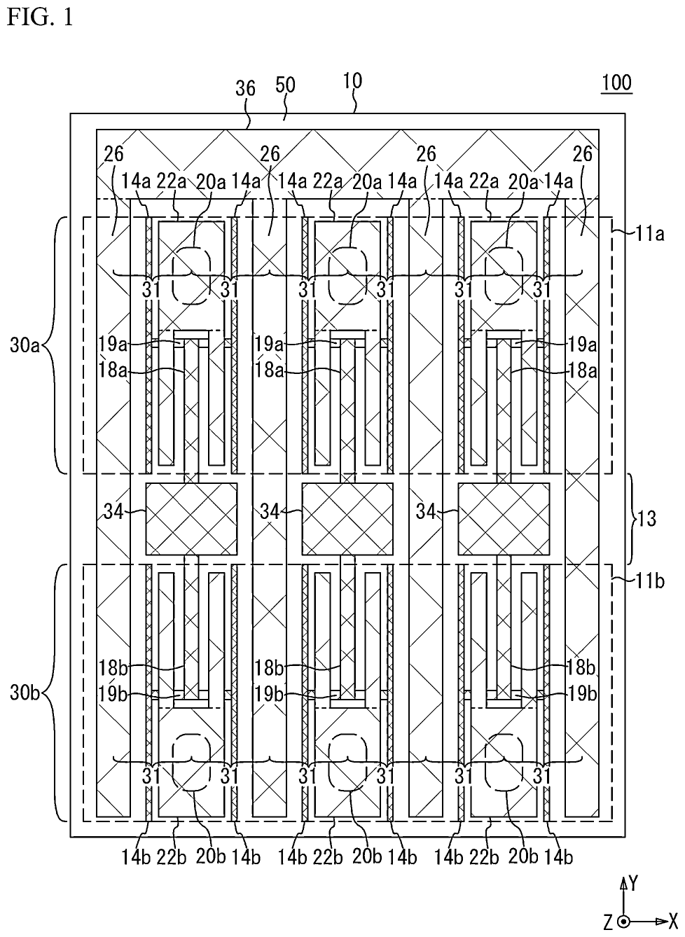

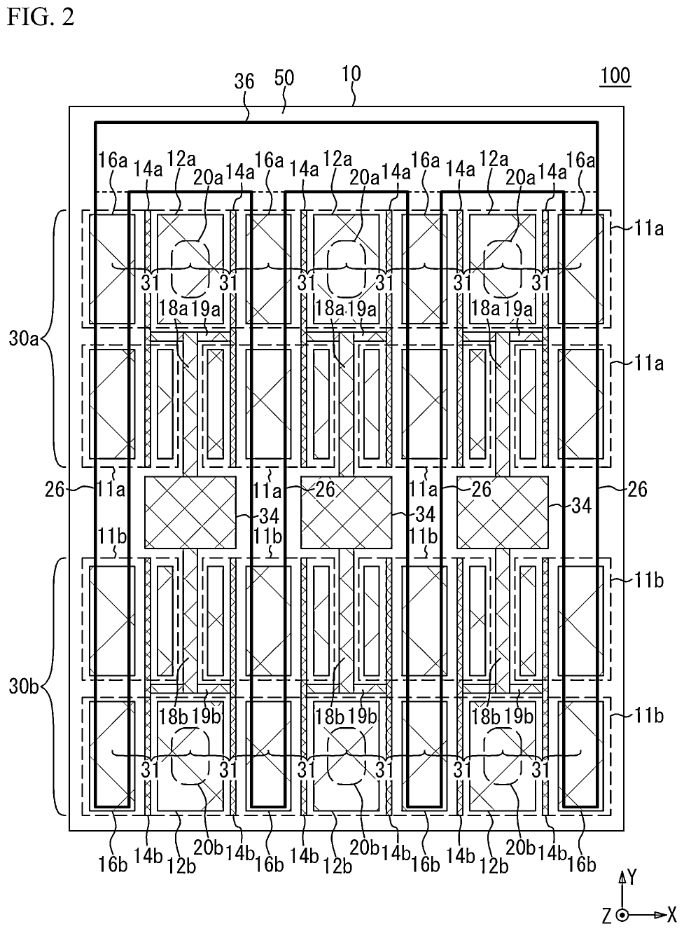

A semiconductor device used in an amplifier for amplifying a high frequency signal from 0.5 GHz to 10 GHz in a base transceiver station of mobile communication will be described as an example. FIG. 1 and FIG. 2 are plan views of a semiconductor device according to a first embodiment. In FIG. 1, source electrodes 12a and 12b and drain electrodes 16a and 16b are not illustrated. Further, active regions 11a and 11b are not illustrated in detail. In the plan view of FIG. 2, when drain electrodes 16a and 16b overlap a drain wire 26, it is difficult to see drain electrodes 16a and 16b. Thus, in FIG. 2, drain wire 26 is seen through, and a thick line illustrating only the outer periphery of drain wire 26 is illustrated inside drain electrodes 16a and 16b. Further, source wires 22a and 22b are not illustrated.

The thickness direction of a substrate 10 is referred to as Z direction, the extending direction of a finger-shaped gate electrodes 14a and 14b is referred to as Y direction (second direction), and the arrangement direction of source electrode 12a, gate electrode 14a, and drain electrode 16a is referred to as X direction (first direction).

As illustrated in FIG. 1 and FIG. 2, in a semiconductor device 100 of first embodiment, an FET group 30a (first FET group) and an FET group 30b (second FET group) are arranged in the Y direction on a main surface 50 of substrate 10. Each of FET groups 30a and 30b includes a plurality of FETs 31 arranged in the X direction. FET 31 in FET group 30a is provided on active region 11a (first active region), and includes source electrode 12a (first source electrode), gate electrode 14a (first gate electrode), and drain electrode 16a (first drain electrode), each of which has a finger shape extending in the Y direction. The plurality of source electrodes 12a and the plurality of drain electrodes 16a are alternately provided in the X direction. One of the plurality of gate electrodes 14a is interposed between one of the plurality of source electrodes 12a and one of the plurality of drain electrodes 16a in the X direction.

FET 31 in FET group 30b is provided on active region 11b (second active region) and includes source electrode 12b (second source electrode), gate electrode 14b (second gate electrode), and drain electrode 16b (second drain electrode), each of which has a finger shape extending in the Y direction. The plurality of source electrodes 12b and the plurality of drain electrodes 16b are alternately provided in the X direction. One of the plurality of gate electrodes 14b is interposed between one of the plurality of source electrodes 12b and one of the plurality of drain electrodes 16b in the X direction. When viewed in the Y direction, the plurality of source electrodes 12b overlap the plurality of source electrodes 12a, respectively, and the plurality of drain electrodes 16b overlap the plurality of drain electrodes 16a, respectively.

A plurality of gate pads 34 (first gate pads) overlap source electrode 12a and source electrode 12b when viewed in the Y direction, are provided on an inactive region 13 of main surface 50 between source electrode 12a and source electrode 12b, and are electrically connected to gate electrode 14a and gate electrode 14b.

Gate wires 18a (first gate wire) and 19a electrically connecting gate pad 34 and gate electrode 14a and gate wires 18b (second gate wire) and 19b electrically connecting gate pad 34 and gate electrode 14b are provided on main surface 50.

Drain wire 26 extends in the Y direction and is provided on drain electrodes 16a and 16b. Drain wire 26 electrically connects and short-circuits drain electrodes 16a and 16b to a drain pad 36. Drain wire 26 electrically connects drain electrode 16a and drain electrode 16b.

The plurality of drain wires 26 are alternately provided with gate pads 34 on main surface 50 between corresponding drain electrode 16a and corresponding drain electrode 16b.

When viewed in the Z direction, a via hole 20a (first via hole) and a via hole 20b (second via hole) overlap source electrodes 12a and 12b, respectively.

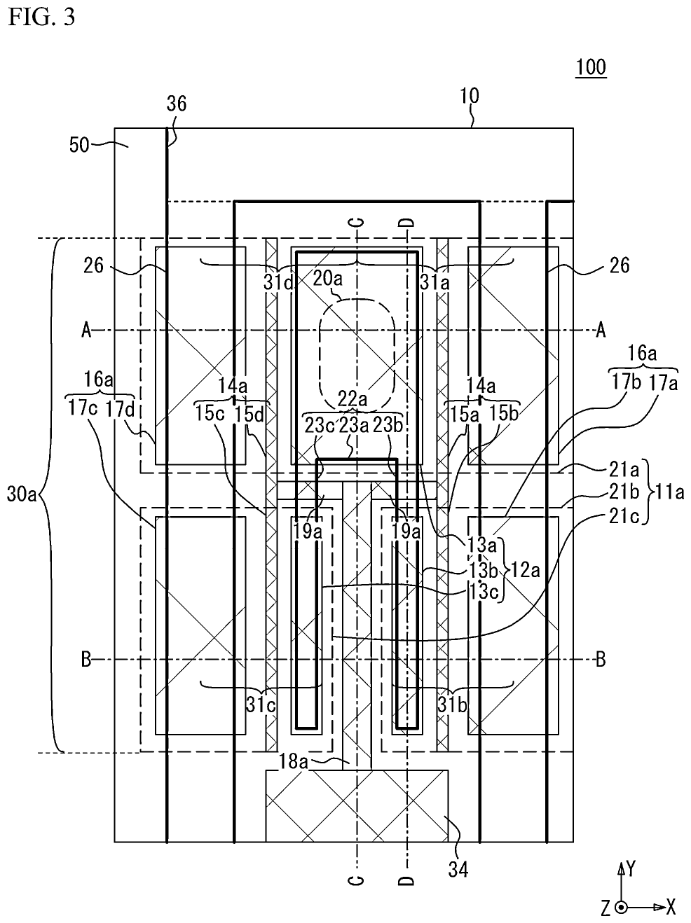

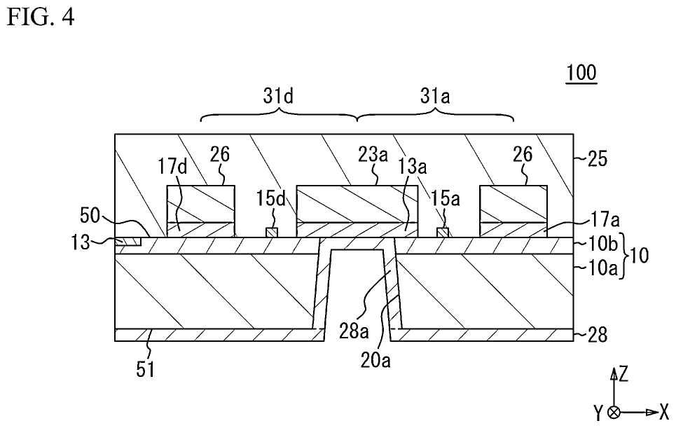

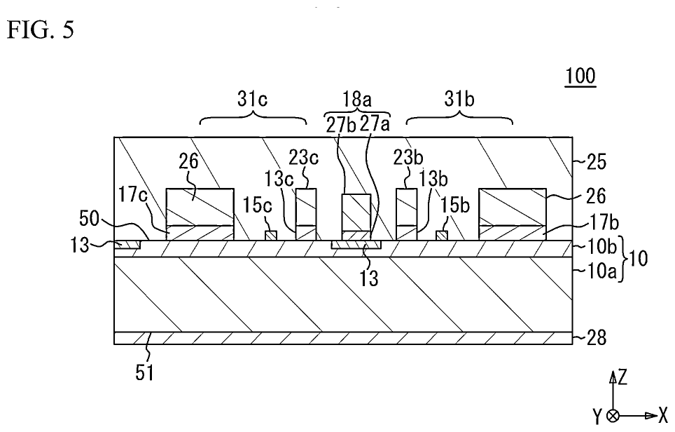

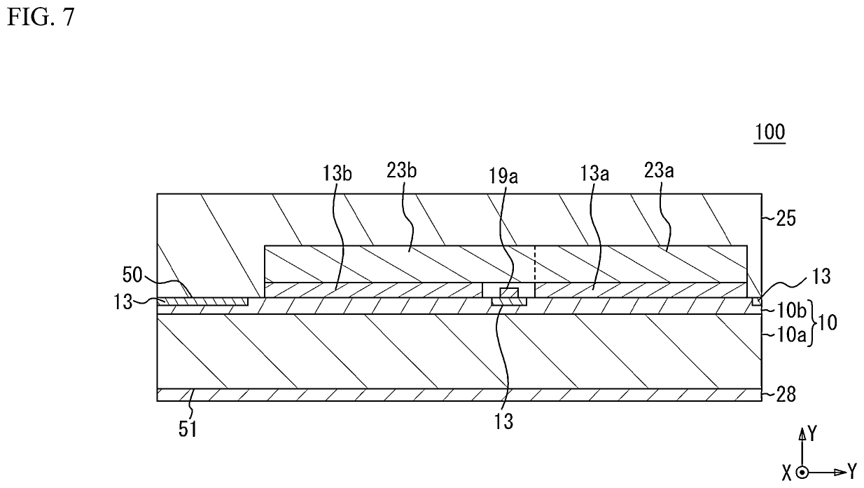

FIG. 3 is an enlarged plan view of the semiconductor device according to the first embodiment. FIG. 4 to FIG. 7 are the A-A cross-sectional view, the B-B cross-sectional view, the C-C cross-sectional view and the D-D cross-sectional view of FIG. 3, respectively.

As illustrated in FIG. 3 to FIG. 7, substrate 10 has main surface 50 and a back surface 51 opposed to main surface 50. Substrate 10 includes a substrate 10a and a semiconductor layer 10b provided on substrate 10a. In the XY plane parallel to the X and Y directions, in semiconductor layer 10b, an inactive region formed by ion implantation or the like is inactive region 13, and regions that are not inactivated (that is, parts of substrate 10 that are activated) are active regions 11a and 11b. Active region 11a has active portions 21a to 21c. Source electrode 12a has source portions 13a to 13c. Gate electrode 14a has gate portions 15a to 15d. Drain electrode 16a has drain portions 17a to 17d. Source wire 22a has wire portions 23a to 23b.

Active portion 21a extends in the X direction. Active portions 21b and 21c are arranged in the X direction. Active portion 21a is provided with an FET 31a and an FET 31d. Active portions 21b and 21c are provided with FETs 31b and 31c, respectively.

FET 31a includes source portion 13a, gate portion 15a, and drain portion 17a. Gate portion 15a is interposed between source portion 13a and drain portion 17a in the X direction. Source portion 13a, gate portion 15a, and drain portion 17a are aligned in order in the + direction of the X direction.

FET 31d includes source portion 13a, gate portion 15d, and drain portion 17d. Gate portion 15d is interposed gate portion 15d between source portion 13a and drain portion 17d in the X direction. Source portion 13a, gate portion 15d, and drain portion 17d are aligned in order in the − direction of the X direction. FETs 31a and 31d share source portion 13a.

FET 31b includes source portion 13b, gate portion 15b, and drain portion 17b. Gate portion 15b is interposed between source portion 13b and drain portion 17b in the X direction. Source portion 13b is provided in source portion 13a when viewed in the Y direction. That is, source portion 13b is not provided outside source portion 13a when viewed in the Y direction. Drain portion 17b overlaps drain portion 17a when viewed in the Y direction. Source portion 13b, gate portion 15b, and drain portion 17b are aligned in order in the + direction of the X direction.

FET 31c includes source portion 13c, a gate portion 15c, and drain portion 17c. Gate wire 18a is interposed between source portion 13c and source portion 13b, and is provided inside source portion 13a when viewed in the Y direction. That is, source portion 13c is not provided outside source portion 13a when viewed in the Y direction. Drain portion 17c overlaps drain portion 17d when viewed in the Y direction. Gate portion 15c is interposed between source portion 13c and drain portion 17c in the X direction. Source portion 13c, gate portion 15c, and drain portion 17c are aligned in order in the − direction of the X direction.

Wire portions 23a to 23c are provided on source portions 13a to 13c, respectively, in contact therewith. Wire portion 23b electrically connects source portion 13b and wire portion 23a. Wire portion 23c electrically connects source portion 13c and wire portion 23a. Thus, source portions 13a to 13c are electrically short-circuited and have the same potential.

Drain wire 26 on the right side of FIG. 3 electrically connects drain portions 17a and 17b to drain pad 36. Drain wire 26 on the left side of FIG. 3 electrically connects drain portions 17d and 17c to drain pad 36.

Gate wire 18a extending in the Y direction is provided on inactive region 13 between FETs 31b and 31c. Gate wire 18a is provided in source portion 13a when viewed in the Y direction. That is, gate wire 18a is not provided outside source portion 13a when viewed in the Y direction. Gate wire 18a is electrically connected to gate pad 34.

Gate wires 19a extending in the X direction are provided on inactive region 13 between FETs 31a and 31b and between FETs 31d and 31c. Gate wire 19a crosses wire portions 23b and 23c in a non-contact manner and electrically connects gate wire 18a and gate portions 15a to 15d. Thus, gate portions 15a to 15d are electrically connected to gate pad 34 through gate wires 18a and 19a, and are short-circuited to have the same potential.

Gate wire 18a and gate pad 34 include a gate metal layer 27a provided on substrate 10 and a wire layer 27b provided on gate metal layer 27a. Gate wire 19a includes gate metal layer 27a, but does not include wire layer 27b.

Via hole 20a penetrates substrate 10. Via holes 20a overlap source portions 13a when viewed in the Z direction, and are electrically connected to source portions 13a. A metal layer 28 is provided on back surface 51 of substrate 10. A metal layer 28a is provided on the inner surface of via hole 20a. Thus, metal layer 28 (back-surface metal layer) is electrically connected to source portion 13a through via hole 20a, and is short-circuited to have the same potential. The planar shape of via holes 20a and 20b may be an ellipse, an oval, a rounded rectangle, or a circle.

A source potential (for example, a reference potential such as a ground potential) is supplied from metal layer 28 to source portion 13a through metal layer 28a in via hole 20a. Further, the source potential is supplied from wire portion 23a to source portions 13b and 13c through wire portions 23b and 23c, respectively. The gate potential (for example, a high frequency signal and a gate bias voltage) is supplied from gate pad 34 to gate portions 15a to 15d through gate wires 18a and 19a. The drain bias voltage is supplied from drain pad 36 to drain portions 17a to 17d through drain wire 26. The high frequency signal amplified in each of FETs 31a to 31d is output from drain wire 26 to drain pad 36.

When semiconductor device 100 is, for example, a nitride semiconductor device, substrate 10a is, for example, a silicon carbide (SiC) substrate, a silicon (Si) substrate, a gallium nitride (GaN) substrate, or a sapphire (Al₂O₃) substrate. Semiconductor layer 10b includes, for example, a nitride semiconductor layer such as a gallium nitride layer, an aluminum gallium nitride (AlGaN) layer, and/or an indium gallium nitride (InGaN) layer. When FET 31 is a gallium nitride high electron mobility transistor (GaN HEMT), semiconductor layer 10b includes a gallium nitride channel layer provided on substrate 10a and an aluminum gallium nitride barrier layer provided on the channel layer. When semiconductor device 100 is, for example, a gallium arsenide (GaAs) based semiconductor device, substrate 10a is, for example, a gallium arsenide substrate. Semiconductor layer 10b includes an arsenide semiconductor layer such as a gallium arsenide layer, an aluminum gallium arsenide (AlGaAs) layer, and/or an indium gallium arsenide (InGaAs) layer. Semiconductor device 100 may be a silicon semiconductor device such as a laterally diffused metal oxide semiconductor (LDMOS).

Source electrodes 12a and 12b and drain electrodes 16a and 16b are metal films, and are, for example, a titanium film and an aluminum film from substrate 10. Gate electrodes 14a and 14b and gate metal layer 27a are metal films, and are, for example, a nickel film and a gold film from substrate 10. Source wires 22a and 22b, drain wire 26, and wire layer 27b are, for example, a gold layer, a copper layer, or an aluminum layer. An insulating layer 25 provided on substrate 10 so as to cover FET 31 is an organic insulating layer such as a polyimide layer or a benzocyclobutene (BCB) layer.

The width of source portion 13a in the X direction is, for example, 50 μm to 150 μm. The width of source portions 13b and 13c in the X direction is, for example, 5 μm to 20 μm. The gate length of gate portions 15a to 15d in the X direction is, for example, 0.25 μm to 2 μm. The width of drain portions 17a to 17d in the X direction is, for example, 5 μm to 150 μm. The width of gate wire 18a in the X direction is, for example, 5 μm to 20 μm. The width of gate wire 19a in the Y direction is, for example, 3 μm to 20 μm. To reduce the gate resistance, the width of gate wire 18a in the X direction and the width of gate wire 19a in the Y direction are larger than the gate length, for example, twice or more the gate length. The gate width of FETs 31a to 31d in the Y direction is, for example, 100 μm to 400 μm. The width of via holes 20a and 20b in the X direction is, for example, 10 μm to 60 μm.

The widths of wire portions 23a to 23c in the X direction are the same as or slightly smaller than the widths of source portions 13a to 13c in the X direction, respectively. The width of drain wire 26 in the X direction is the same as or slightly smaller than the width of drain portions 17a to 17d in the X direction.

### First Comparative Example

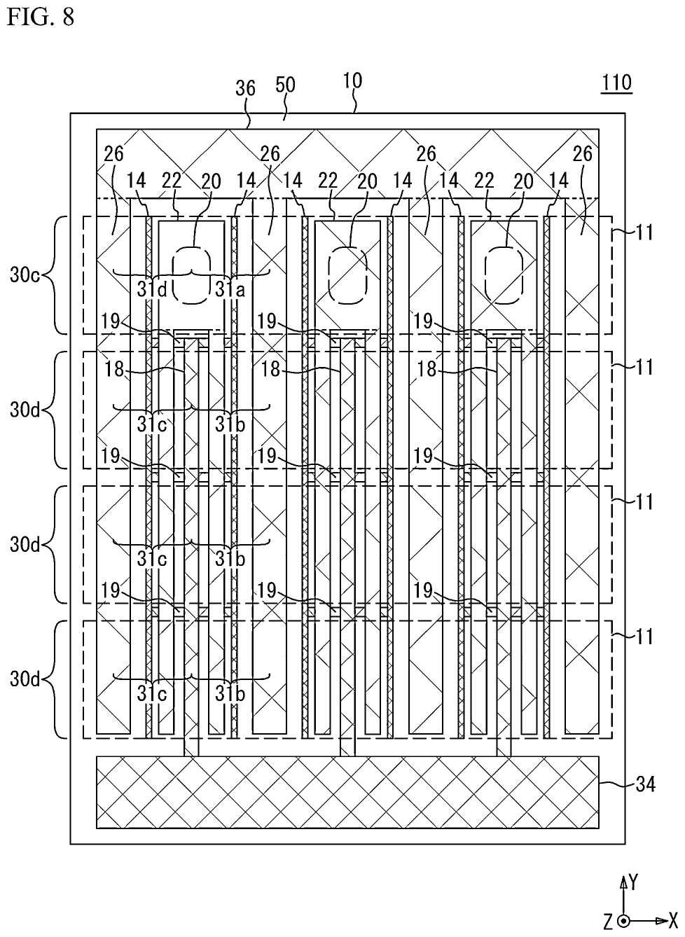

FIG. 8 is a plan view of a semiconductor device according to a first comparative example. As illustrated in FIG. 8, a semiconductor device 110 of the first comparative example is provided with an FET group 30c having FETs 31a and 31d of FIG. 3. A plurality of FET groups 30d each including FET 31b and FET 31c are aligned in the Y direction. Gate pad 34 and drain pad 36 are provided such that FET group 30c and the plurality of FET groups 30d are interposed between gate pad 34 and drain pad 36. A gate wire 18 is connected to gate pad 34. A gate wire 19 electrically connects a gate electrode 14 and gate wire 18 between FET group 30c and FET group 30d and between the plurality of FET groups 30d.

In the first comparative example, the gate resistance between gate electrode 14 and gate pad 34 can be reduced by using gate wires 18 and 19. However, the source inductance increases because source wire 22 becomes long. This causes deterioration in high frequency characteristics. In addition, since gate electrode 14 serving as a heat source is dense, the thermal resistance is increased.

### Second Comparative Example

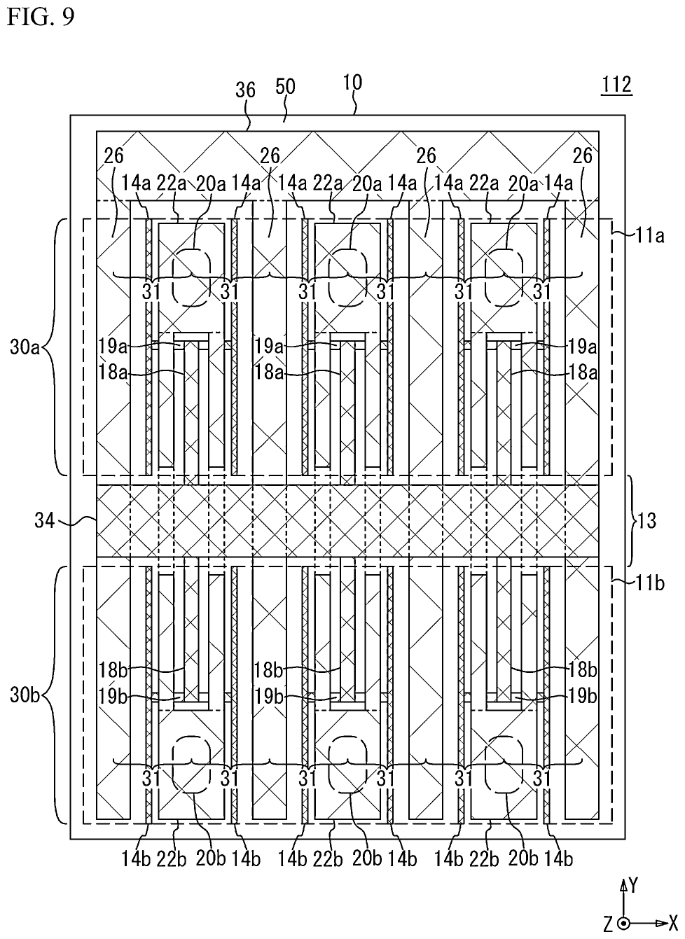

FIG. 9 is a plan view of a semiconductor device according to a second comparative example. As illustrated in FIG. 9, in a semiconductor device 112 of the second comparative example, gate pad 34 is provided between FET groups 30a and 30b. Gate pad 34 is provided above source wires 22a and 22b and drain wire 26 in the Z direction.

In the second comparative example, gate pad 34 is provided between FET groups 30a and 30b, and via holes 20a and 20b are provided in both FET groups 30a and 30b, so that source wires 22a and 22b can be shortened. This can reduce the source inductance. In addition, the distance between gate electrodes 14a and 14b, which are heat sources, is increased. This can reduce the thermal resistance.

However, in the second comparative example, gate pad 34 overlaps source wires 22a and 22b and drain wire 26 when viewed in the Z direction. Thus, the gate-drain capacitance and the gate-source capacitance increase. This causes deterioration in high frequency characteristics.

### Description of First Embodiment

According to the first embodiment, as illustrated in FIG. 1 and FIG. 2, gate pad 34 is provided between source electrodes 12a and 12b. Drain wires 26 are alternately provided with gate pads 34 between drain electrodes 16a and 16b.

Thus, gate pad 34 does not overlap source wires 22a and 22b and drain wire 26. Thus, the gate-drain capacitance and the gate-source capacitance can be reduced as compared with the second comparative example. In addition, the source inductance can be reduced as compared with the first comparative example. FET group 30a is interposed between drain pad 36 and gate pad 34. Thus, as described in Patent literature 1 and 2, the gate-drain capacitance between the gate pad and the drain pad can be reduced. Thus, the high frequency characteristics can be improved as compared with the first and second comparative examples and Patent literature 1 and 2.

Further, since FET groups 30a and 30b are separated from each other, the thermal resistance can be reduced as compared with the first comparative example.

### [Simulation]

As an example, thermal simulation was performed for the first embodiment and the first comparative example. In the simulation, 88 gate electrodes 14 were aligned in the X direction on the SiC substrate. In the first embodiment, the distance between FET groups 30a and 30b was 130 μm. As a result of the simulation, the maximum temperatures of the upper surface of the SiC substrate in the first embodiment and the first comparative example were 120.1° C. and 125.4° C., respectively. As described above, the thermal resistance of the first embodiment is lower than that of the first comparative example, and the maximum temperature can be reduced.

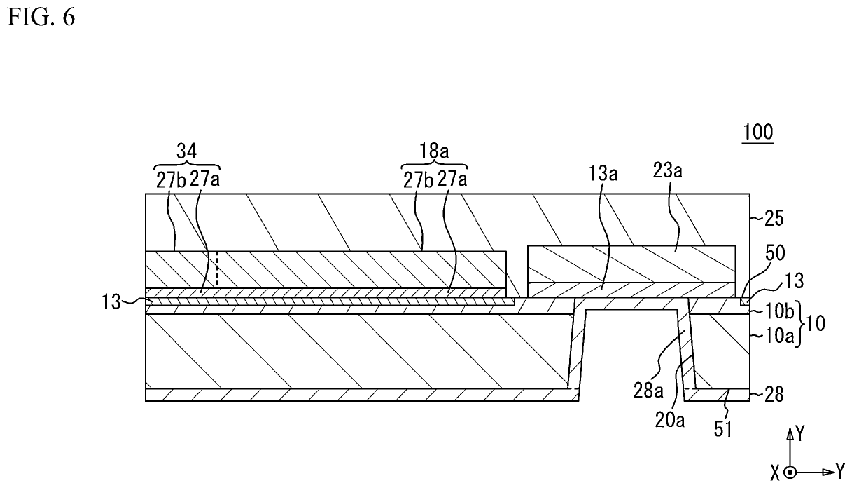

As illustrated in FIG. 1, FIG. 4 and FIG. 6, metal layer 28 (back-surface metal layer) is electrically connected to the plurality of source electrodes 12a and 12b through the plurality of via holes 20a and 20b, respectively. Thus, since the source potential can be supplied to source electrodes 12a and 12b, the source inductance can be reduced and the high frequency characteristics can be improved.

As illustrated in FIG. 1, the plurality of gate pads 34 are provided in inactive region 13. Thus, the gate-source capacitance can be reduced, and the high frequency characteristics can be improved.

As illustrated in FIG. 3 to FIG. 7, source electrode 12a includes source portion 13a (first portion), source portion 13b (second portion), and source portion 13c (third portion). Source portions 13b and 13c overlap source portion 13a when viewed in the Y direction, and are provided between source portion 13a and gate pad 34. Gate wire 18a is provided between source portions 13b and 13c and electrically connects gate electrode 14a and gate pad 34. Thus, the gate resistance in FET group 30a can be reduced without increasing the size. Thus, high frequency characteristics can be improved.

Similarly, source electrode 12b includes source portion 13a (fourth portion), source portion 13b (fifth portion), and source portion 13c (sixth portion). Gate wire 18b is provided between source portions 13b and 13c, and electrically connects gate electrode 14b and gate pad 34. Thus, the gate resistance in FET group 30b can be reduced without increasing the size. Thus, high frequency characteristics can be improved.

### First Modification of First Embodiment

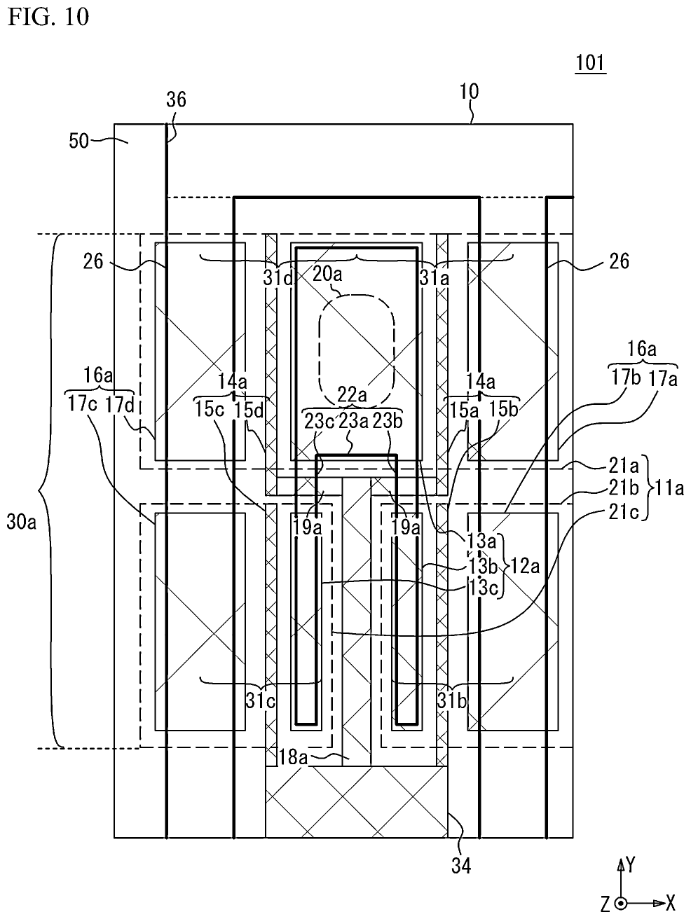

FIG. 10 is an enlarged plan view of a semiconductor device according to a first modification of the first embodiment. As illustrated in FIG. 10, in a semiconductor device 101 of the first modification of the first embodiment, gate portions 15a and 15b are separated from each other and gate portions 15d and 15c are separated from each other in FET group 30a. Gate portions 15a and 15d are electrically connected to gate pad 34 through gate wires 19a and 18a. Gate portions 15b and 15c are electrically connected to gate pad 34 without gate wires 18a and 19a. Other configurations are the same as those of the first embodiment, and the description thereof is omitted. As in the first modification of the first embodiment, some of gate portions 15a to 15d may be electrically connected to gate pad 34 through gate wires 18a and 19a.

### Second Modification of First Embodiment

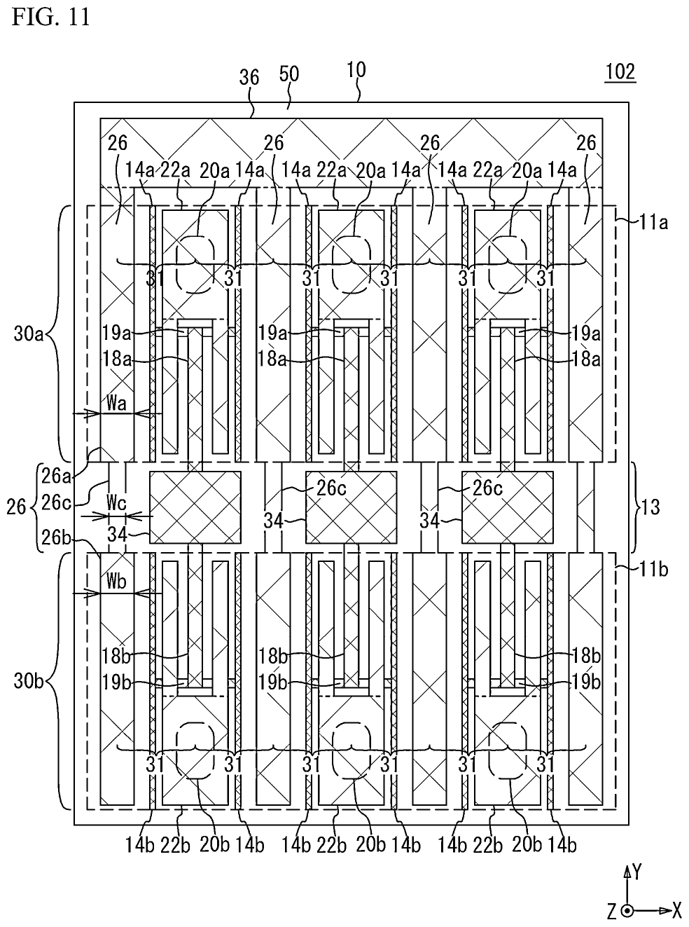

FIG. 11 is a plan view of a semiconductor device according to a second modification of the first embodiment. As illustrated in FIG. 11, in a semiconductor device 102 of the second modification of the first embodiment, drain wire 26 includes portions 26a to 26c. Portions 26a and 26b are provided respectively in FET groups 30a and 30b. Portion 26c is a portion between FET groups 30a and 30b. A width Wc of portion 26c in the X direction is narrower than width Wa of drain electrode 16a and portion 26a in the X direction and width Wb of drain electrode 16b and portion 26b in the X direction. Other configurations are the same as those of the first embodiment, and the description thereof is omitted.

According to the second modification of the first embodiment, width Wc of drain wire 26 in the X direction between FET groups 30a and 30b is smaller than width Wa of drain electrode 16a and portion 26a in the X direction and width Wb of drain electrode 16b and portion 26b in the X direction. Thus, the distance between gate pad 34 and drain wire 26 is increased, and the gate-drain capacitance can be reduced. Thus, high frequency characteristics can be improved. Width Wc can be 0.9 times or less, 0.8 times or less, or 0.6 times or less width Wa or Wb. When the lengths of FET groups 30a and 30b in the Y direction are substantially the same, the density of the current flowing through portion 26c can be equal to the density of the current flowing through portion 26a at a position close to drain pad 36 when width Wc is about 0.5 times widths Wa and Wb. Thus, width Wc can be 0.5 times or more widths Wa and Wb.

### Third Modification of First Embodiment

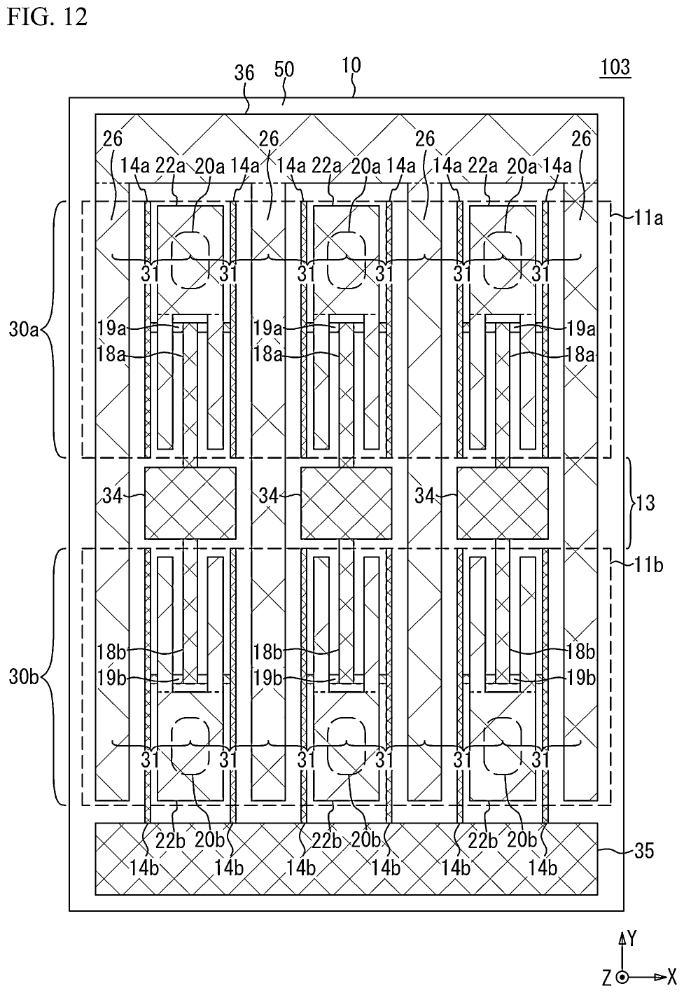

FIG. 12 is a plan view of a semiconductor device according to a third modification of the first embodiment. As illustrated in FIG. 12, in a semiconductor device 103 of the third modification of the first embodiment, a gate pad 35 (second gate pad) is provided in addition to gate pad 34. Gate pad 35 is provided such that FET group 30b is interposed between gate pad 34 and gate pad 35 on main surface 50. Gate electrode 14b is electrically connected directly to gate pad 35. Other configurations are the same as those of the first embodiment, and the description thereof is omitted.

According to the third modification of the first embodiment, by providing gate pads 34 and 35, bonding wires can be bonded to the gate pads at two positions in the Y direction.

### Fourth Modification of First Embodiment

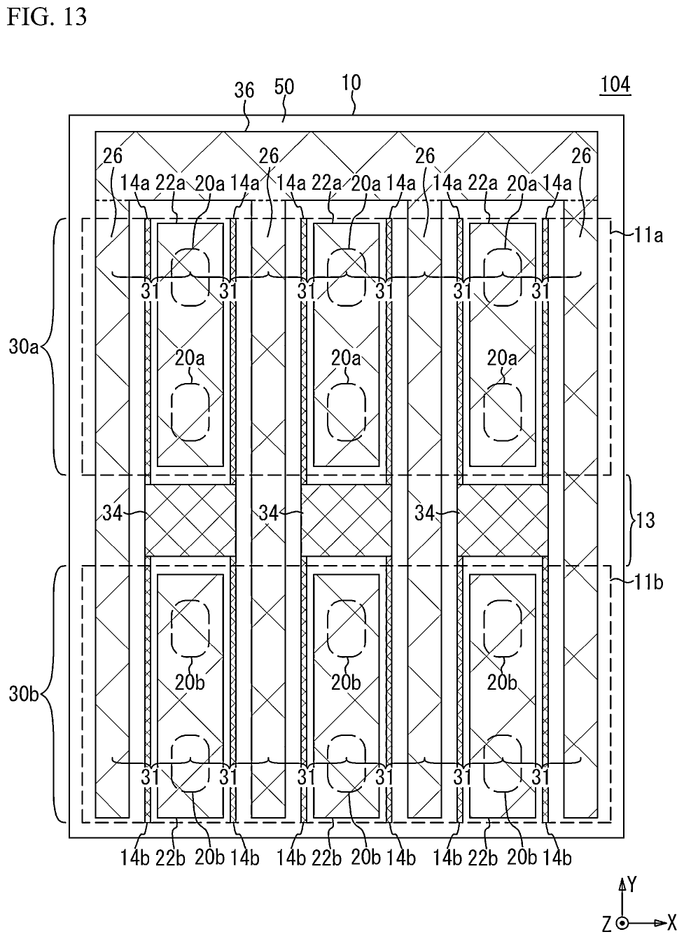

FIG. 13 is a plan view of a semiconductor device according to a fourth modification of the first embodiment. As illustrated in FIG. 13, a semiconductor device 104 of the fourth modification of the first embodiment is not provided with gate wires 18a, 18b, 19a and 19b. The planar shapes of source electrodes 12a and 12b and source wires 22a and 22b are rectangular. Thus, semiconductor device 104 is a multi-finger type FET. Gate pad 34 is provided between FET groups 30a and 30b. Other configurations are the same as those of the first embodiment, and the description thereof is omitted.

In the fourth modification of the first embodiment, gate wires 18a, 18b, 19a, and 19b are not provided, and thus the gate resistance is increased as compared with the first embodiment. However, as compared with a general multi-finger type FET, the gate resistance can be reduced and the high frequency characteristics can be improved.

### Fifth Modification of First Embodiment

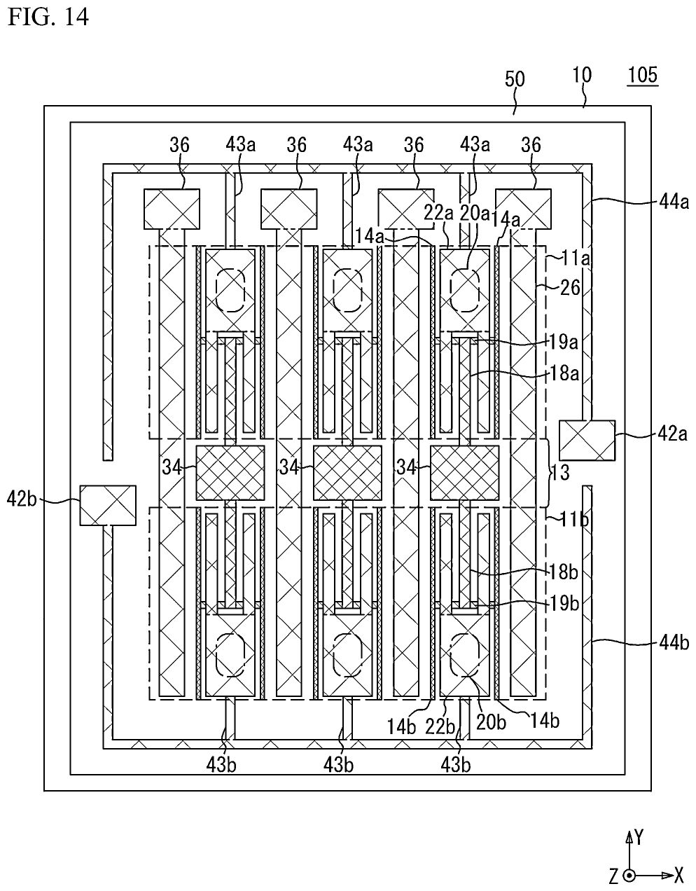

FIG. 14 is a plan view of a semiconductor device according to a fifth modification of the first embodiment. As illustrated in FIG. 14, in a semiconductor device 105 of the fifth modification of the first embodiment, guard rings 44a and 44b are provided on main surface 50 so as to surround FET groups 30a and 30b. A plurality of drain pads 36 are provided corresponding to drain wires 26. Guard ring 44a is electrically connected to source wire 22a through a connection wire 43a provided between the plurality of drain pads 36. Guard ring 44b is electrically connected to source wire 22b through a connection wire 43b. Guard rings 44a and 44b are electrically connected to source pads 42a and 42b. Other configurations are the same as those of the first embodiment, and the description thereof is omitted.

In the fifth modification of the first embodiment, guard rings 44a and 44b are electrically connected to source electrodes 12a and 12b on main surface 50 and surround FET groups 30a and 30b. This makes it possible to shield FET groups 30a and 30b. Guard rings 44a and 44b may partially surround FET groups 30a and 30b, but may also completely surround them. By providing source pads 42a and 42b, the characteristics of FET groups 30a and 30b can be evaluated before via holes 20a and 20b are formed. Although drain pad 36 may be provided integrally, connection wire 43a can be provided by dividing drain pad 36 into a plurality of parts. A connection wire for electrically connecting gate electrode 14b may be provided between source wire 22b and guard ring 44b. Connection wires 43a and 43b may not be provided.

In the first embodiment and the modification thereof, the example in which six FETs 31 are provided in the X direction has been described, but eight or more FETs 31 may be provided in the X direction. In each of FET groups 30a and 30b, the example in which two FETs 31 are provided in the Y direction has been described, but three or more FETs 31 may be provided in the Y direction.

In the first embodiment and the modification thereof, drain portions 17a and 17b (and 17d and 17c) electrically connected to same drain wire 26 are separated from each other in inactive region 13. The plurality of drain portions 17a to 17d electrically connected by drain wire 26 may be connected to each other in inactive region 13. In FET 31, source electrode 12a and source wire 22a can be collectively referred to as a source electrode, and drain electrode 16a and drain wire 26 can be collectively referred to as a drain electrode.

### Second Embodiment

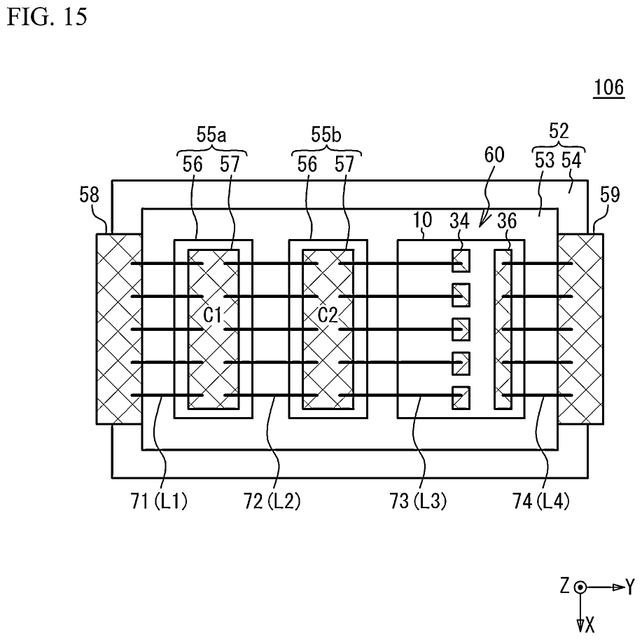

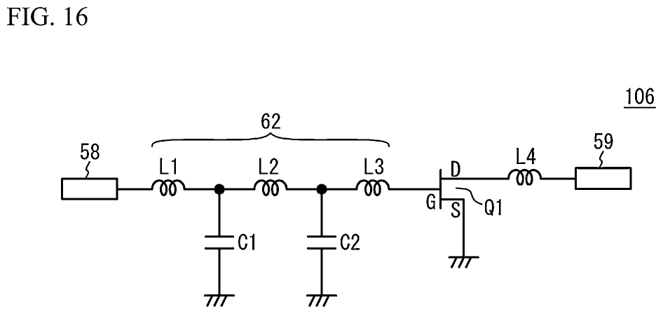

A second embodiment and its modification are examples of a semiconductor device in which the semiconductor chip of the first embodiment and its modification is mounted in a package. FIG. 15 is a plan view of a semiconductor device according to the second embodiment. FIG. 16 is an equivalent circuit diagram of FIG. 15. In FIG. 15, the lid of a package 52 is not illustrated.

As illustrated in FIG. 15, in a semiconductor device 106 of the second embodiment, package 52 has a base 53, a frame body 54, and a lid, at least the upper surfaces of which are conductive. Base 53 is a conductive substrate such as a copper-molybdenum laminated substrate. A reference potential such as a ground potential is supplied to base 53. Frame body 54 and the lid are dielectric layers made of, for example, a resin such as a glass epoxy resin or a ceramic. A semiconductor chip 60 and capacitive components 55a and 55b are mounted on base 53. Frame body 54 is provided on base 53 so as to surround semiconductor chip 60 and capacitive components 55a and 55b. The lid is bonded to the upper surface of frame body 54 with an insulating adhesive such as a resin. Frame body 54 and the lid seal semiconductor chip 60 in a space.

Frame body 54 has a substantially rectangular planar shape. A lead 58 (input lead) is provided on the − side of frame body 54 in the Y direction. A lead 59 (output lead) is provided on the + side of frame body 54 in the Y direction. Leads 58 and 59 are, for example, metal layers or metal plates made of copper or the like. A high frequency signal is input to lead 58, and a high frequency signal is output from lead 59. Lead 58, capacitive components 55a and 55b, semiconductor chip 60, and lead 59 are aligned in the Y direction.

Semiconductor chip 60 includes substrate 10, gate pad 34 and drain pad 36 provided on the upper surface of substrate 10, and metal layer 28 provided on the back surface of substrate 10 (see FIG. 4 to FIG. 7). Semiconductor chip 60 corresponds to semiconductor devices 100 to 105 of the first embodiment and modifications thereof. Capacitive components 55a and 55b include a dielectric substrate 56, an electrode 57 provided on the upper surface of dielectric substrate 56, and an electrode provided on the lower surface of dielectric substrate 56. Electrode 57 interposed between dielectric substrate 56 and the lower surface electrode forms a capacitor. Dielectric substrate 56 is, for example, an alumina substrate or a barium titanate substrate. Electrode 57 is a metal layer such as a gold layer.

A bonding wire 71 electrically connects lead 58 and electrode 57 of capacitive component 55a. A bonding wire 72 electrically connects electrode 57 of capacitive component 55a and electrode 57 of capacitive component 55b. A bonding wire 73 electrically connects electrode 57 of capacitive component 55b and gate pad 34. A bonding wire 74 electrically connects drain pad 36 and lead 59.

As illustrated in FIG. 16, a source S of the FETQ1 is grounded, a gate G is electrically connected to lead 58 through a matching circuit 62, and a drain D is electrically connected to lead 59. Inductors L1 to L3 are connected in series between lead 58 and gate G. A capacitor C1 is shunt-connected to a node between inductor L1 and the L2, and a capacitor C2 is shunt-connected to a node between inductor L2 and the L3. Inductors L1 to L3, capacitors C1 and C2 function as matching circuit 62. An inductor L4 is connected between drain D and lead 59.

The high frequency signal input to lead 58 is input to gate G through matching circuit 62. Matching circuit 62 matches the impedances of lead 58 and gate G with each other. The FETQ1 amplifies the high frequency signal input to gate G, and outputs the amplified high frequency signal to lead 59 through inductor L4.

Inductors L1 to L4 correspond to bonding wires 71 to 74, respectively, and capacitors C1 and C2 correspond to capacitive components 55a and 55b, respectively.

In the second embodiment, bonding wire 73 (first bonding wire) is connected to gate pad 34 and extends in the − direction (second direction) in the Y direction. Bonding wire 74 (second bonding wire) is connected to drain pad 36 and extends in the + direction (direction opposite to the second direction) in the Y direction. As a result, as illustrated in FIG. 1 and FIG. 2, since the high frequency signal is input to gate pad 34 between FET groups 30a and 30b, the high frequency signal is equally input to FET groups 30a and 30b. In particular, when matching circuit 62 also processes the harmonic signal, the wavelength of the harmonic signal is shorter than that of the fundamental wave. Thus, as illustrated in FIG. 8 of the first comparative example, when gate electrode 14 is long in the Y direction, the harmonics may not be uniformly processed. In the second embodiment, matching circuit 62 is connected to gate pad 34 between FET groups 30a and 30b, and thus the processing of the harmonic can be made more uniform.

### First Modification of Second Embodiment

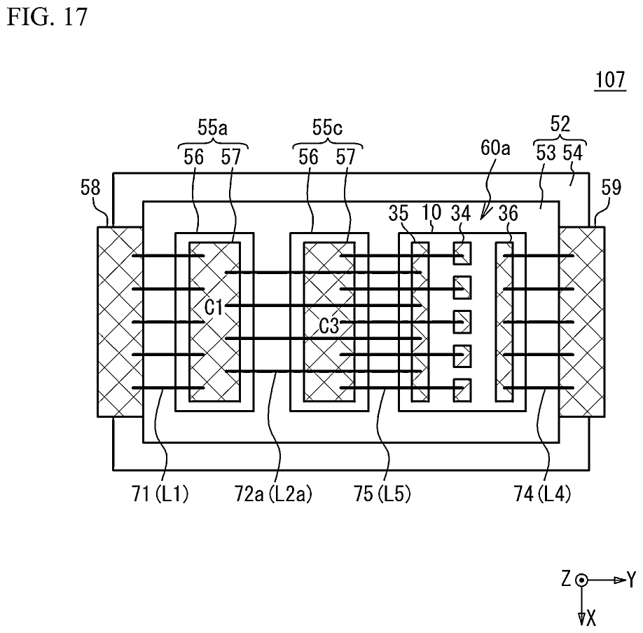

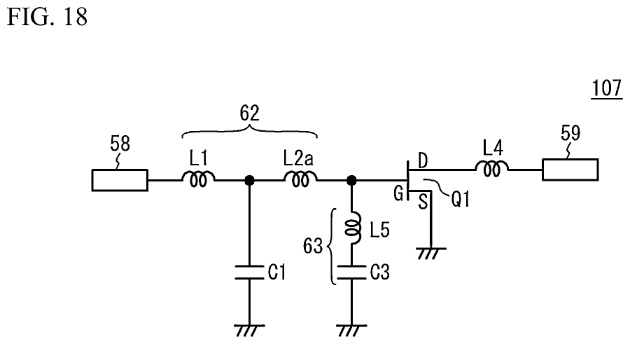

FIG. 17 is a plan view of a semiconductor device in a first modification of the second embodiment. FIG. 18 is an equivalent circuit diagram of FIG. 17. As illustrated in FIG. 17, in a semiconductor device 107 of the first modification of the second embodiment, a capacitive component 55c is mounted on base 53 between capacitive component 55a and a semiconductor chip 60a. Semiconductor chip 60a is semiconductor device 103 of a third modification of the first embodiment. Gate pads 34 and 35 and drain pad 36 are provided on substrate 10. A bonding wire 72a electrically connects electrode 57 of capacitive component 55a and gate pad 35. A bonding wire 75 electrically connects electrode 57 of capacitive component 55c and gate pad 34. Other configurations are the same as those of FIG. 15 of the second embodiment.

As illustrated in FIG. 18, inductors L1 and L2a are connected in series between lead 58 and gate G. Inductor L5 and a capacitor C3 are connected in series between a node and the ground, the node being between an inductor L2a and gate G. Inductors L1, L2a, and capacitor C1 function as matching circuit 62. Inductor L5 and capacitor C3 function as a harmonic processing circuit 63. Harmonic processing circuit 63 has a function of reducing a second harmonic or a third harmonic. For example, the resonance frequencies of the series resonance circuit of inductor L5 and capacitor C3 are set to the frequencies of the harmonics. Thus, the harmonic signal of the harmonic signal input to gate G flows to the ground, and the harmonic can be reduced. Other configurations are the same as those of FIG. 16 of the second embodiment.

### Third Comparative Example

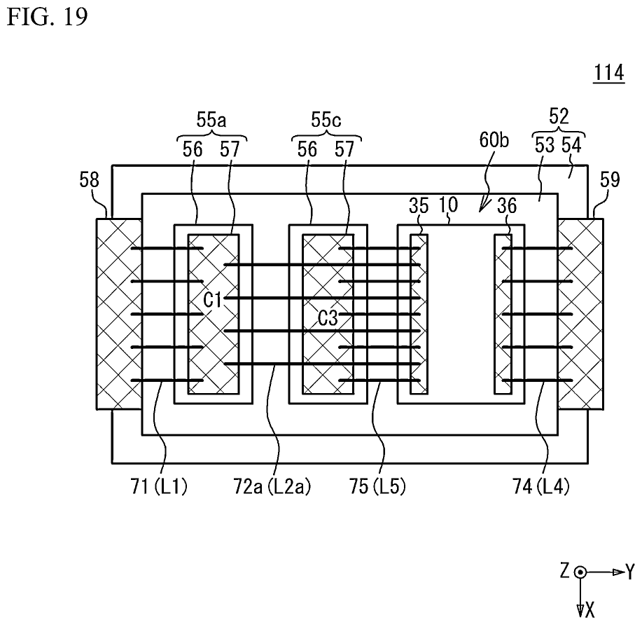

FIG. 19 is a plan view of a semiconductor device according to a third comparative example. As illustrated in FIG. 19, in a semiconductor device 114 of the third comparative example, a semiconductor chip 60b corresponds to semiconductor device 110 of the first comparative example. Gate pad 34 is not provided on substrate 10, but gate pad 35 is provided thereon. Bonding wire 75 is connected to gate pad 35. Other configurations are the same as those of FIG. 17.

The equivalent circuit of the third comparative example is the same as that of FIG. 18. Since bonding wires 72a and 75 are connected to the same gate pad 35, different signals, for example, a signal of matching circuit 62 for the fundamental wave and a signal of harmonic processing circuit 63, may interfere with each other.

In the first modification of the second embodiment, bonding wire 75 is connected to gate pad 34, and bonding wire 72a (third bonding wire) is connected to gate pad 35. This can reduce interference between different signals such as the signal of the fundamental wave from matching circuit 62 and the signal of harmonic processing circuit 63. Capacitor C3 (first capacitor) has a first end electrically connected to base 53 and a second end connected to bonding wire 75. Capacitor C1 (second capacitor) has a first end electrically connected to base 53 and a second end connected to bonding wire 72a. Thus, harmonic processing circuit 63 including capacitor C3 and bonding wire 75 can be formed, and matching circuit 62 including capacitor C1 and bonding wire 72a can be formed. Harmonic processing circuit 63 is connected to gate pad 34, so that the harmonic can be uniformly processed.

The embodiments disclosed herein are to be considered in all respects as illustrative and not restrictive. The scope of the present disclosure is defined by the appended claims rather than the foregoing description, and is intended to include all modifications within the scope and meaning equivalent to the claims.

What is claimed is:

1. A semiconductor device comprising:
a substrate having a main surface and a back surface opposite to the main surface;
a first FET group provided on the main surface and including a plurality of first source electrodes, a plurality of first drain electrodes, and a plurality of first gate electrodes, the plurality of first source electrodes, the plurality of first drain electrodes, and the plurality of first gate electrodes being aligned in a first direction;
a second FET group provided on the main surface and including a plurality of second source electrodes, a plurality of second drain electrodes, and a plurality of second gate electrodes, the second FET group overlapping the first FET group as viewed in a second direction intersecting the first direction;
a plurality of first gate pads provided on the main surface between the first FET group and the second FET group and electrically connected to the plurality of first gate electrodes and the plurality of second gate electrodes;
a plurality of drain wires provided on the main surface to be arranged alternately with the plurality of first gate pads between the first FET group and the second FET group, the plurality of drain wires electrically connecting the plurality of first drain electrodes and the plurality of second drain electrodes to each other; and
a drain pad electrically connected to the plurality of first drain electrodes and disposed such that the first FET group is interposed between the drain pad and the plurality of first gate pads.

2. The semiconductor device according to claim 1, comprising:
a back-surface metal layer provided on the back surface, the back-surface metal layer being electrically connected to the plurality of first source electrodes through a plurality of first via holes overlapping the plurality of first source electrodes, respectively, as viewed in a thickness direction of the substrate and being electrically connected to the plurality of second source electrodes through each of a plurality of second via holes overlapping the plurality of second source electrodes, respectively, as viewed in the thickness direction of the substrate.

3. The semiconductor device according to claim 1,
wherein the first FET group and the second FET group are respectively provided in a first active region and a second active region in each of which the main surface is activated, and the plurality of first gate pads are provided in an inactive region in which the main surface is inactivated, the inactivate region being provided between the first active region and the second active region.

4. The semiconductor device according to claim 1,
wherein a width of each of the plurality of drain wires between the first FET group and the second FET group in the first direction is smaller than a width of each of the plurality of first drain electrodes in the first direction and a width of each of the plurality of second drain electrodes in the first direction.

5. The semiconductor device according to claim 1, further comprising:
a second gate pad provided on the main surface such that the second FET group is interposed between the second gate pad and the plurality of first gate pads, the second gate pad being electrically connected to the plurality of second gate electrodes.

6. The semiconductor device according to claim 1,
wherein each of the plurality of first source electrodes includes a first portion, a second portion, and a third portion, the second portion and the third portion being aligned in the first direction to overlap the first portion as viewed in the second direction and to be provided between the first portion and a corresponding one of the first gate pads, and
wherein the first FET group includes a plurality of first gate wires each provided between the second portion and the third portion and each electrically connecting at least one of the first gate electrodes to the corresponding one of the first gate pads.

7. The semiconductor device according to claim 6,
wherein each of the plurality of second source electrodes includes a fourth portion, a fifth portion, and a sixth portion, the fifth portion and the sixth portion being aligned in the first direction to overlap the fourth portion as viewed in the second direction and to be provided between the fourth portion and a corresponding one of the first gate pads, and
wherein the second FET group includes a plurality of second gate wires each provided between the fifth portion and the sixth portion and each electrically connecting at least one of second gate electrodes to the corresponding one of the first gate pads.

8. The semiconductor device according to claim 1, comprising:
a guard ring electrically connected to the plurality of first source electrodes and the plurality of second source electrodes on the main surface and surrounding the first FET group and the second FET group.

9. The semiconductor device according to claim 1, comprising:
a base;
a semiconductor chip mounted on the base and including the substrate;
a first bonding wire connected to each of the first gate pads and extending in the second direction; and
a second bonding wire connected to the drain pad and extending in a direction opposite to the second direction.

10. The semiconductor device according to claim 5, comprising:
a base;
a semiconductor chip mounted on the base and including the substrate;
a first bonding wire connected to each of the first gate pads and extending in the second direction;
a second bonding wire connected to the drain pad and extending in a direction opposite to the second direction; and
a third bonding wire connected to the second gate pad and extending in the second direction.

11. The semiconductor device according to claim 10, comprising:
a first capacitor mounted on the base and having a first end electrically connected to the base and a second end to which the first bonding wire is connected; and
a second capacitor mounted on the base and having a first end electrically connected to the base and a second end to which the third bonding wire is connected.
